(19) United States
(12) Patent Application Publication
(10) Pub. No.: US 2010/0182737 A1
(43) Pub. Date: Jul. 22, 2010

(54) Electronic Device

(75) Inventors: Naoki Tani, Ome-shi (JP); Hiroyuki Minaguchi, Higashimatsuyama-shi (JP); Toshikazu Shiroishi, Hamura-shi (JP); Masataka Tokoro, Tachikawa-shi (JP); Naohiro Yokoyama, Akishima-shi (JP); Motoki Tomita, Hamura-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/533,769

(22) Filed: Jul. 31, 2009

(30) Foreign Application Priority Data
Jan. 16, 2009 (JP) 2009-008142

(51) Int. Cl. H05K 5/00

(52) U.S. Cl. 361/679.01

(57) ABSTRACT

An electronic apparatus includes: a housing; a heating member in the housing; and a display device in the housing, the display device having a display screen. The housing has: a mask portion including an opening, the opening configured to expose the display screen therethrough; a cover portion provided opposing to the mask portion with respect to the display device; and at least two connecting portions configured to connect the mask portion and the cover portion, and to sandwich the heating member. Each of the at least two connecting portions includes a gap portion that allows expansion and contraction of the housing due to thermal expansion between the connecting portion and at least one of the mask portion and the cover portion.

### CROSS-REFERENCE TO RELATED APPLICATIONS

This application is based upon and claims the benefit of priority from Japanese Patent Application No. 2009-008142, filed on Jan. 16, 2009, the entire contents of which are incorporated herein by reference.

### BACKGROUND

1. Field

An aspect of the present invention relates to an electronic apparatus.

2. Description of the Related Art

An electronic apparatus such as a portable computer includes a display unit. The display unit includes a housing, and a display device which is housed in the housing.

For example, U.S. Pat. No. 6,992,884 B2 discloses an electronic apparatus including a bracket which absorbs a dimensional difference between a housing and a display device. The bracket disclosed in U.S. Pat. No. 6,992,884 B2 has a first portion which is fixed to the display device, a second portion which is fixed to the housing, and a connecting portion through which the first portion is connected to the second portion.

The second portion (i.e., the portion fixed to the housing) of the bracket disclosed in U.S. Pat. No. 6,992,884 B2 has a mounting hole which is disposed directly in the side of the display device. A screw which is inserted into the mounting hole of the bracket is engaged with a screw hole of the housing, whereby the bracket is fixed to the housing. In such an electronic apparatus, when a part of the housing is deformed by thermal expansion or the like, stress is applied between the display device and the screw, and may possibly cause the display device to be broken.

### BRIEF DESCRIPTION OF THE SEVERAL VIEWS OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 is an exemplary perspective view of a portable computer of a first embodiment of the invention;

FIG. 2 is an exemplary exploded perspective view showing a display unit in the first embodiment;

FIG. 3 is an exemplary perspective view of a cover and bracket in the first embodiment;

FIG. 4 is an exemplary plan view schematically showing the interior of the display unit in the first embodiment;

FIG. 5 is an exemplary sectional view of the display unit in the first embodiment;

FIG. 6 is an exemplary sectional view showing a step of connecting the display unit in the first embodiment;

FIG. 7 is an exemplary sectional view of the interior of the display unit in the first embodiment;

FIG. 8 is an exemplary sectional view showing a step of connecting the display unit in the first embodiment;

FIG. 9 is an exemplary sectional view of the interior of a display unit in a second embodiment; and

FIG. 10 is an exemplary sectional view of the interior of the display unit in the second embodiment.

### DETAILED DESCRIPTION

Various embodiments according to the present invention will be described hereinafter with reference to the accompanying drawings. In general, according to one embodiment of the present invention, there is provided an electronic apparatus including: a housing; a heating member in the housing; and a display device in the housing, the display device having a display screen, wherein the housing has: a mask portion including an opening, the opening configured to expose the display screen therethrough; a cover portion provided opposing to the mask portion with respect to the display device; and at least two connecting portions configured to connect the mask portion and the cover portion, and to sandwich the heating member, wherein each of the at least two connecting portions includes a gap portion that allows expansion and contraction of the housing due to thermal expansion between the connecting portion and at least one of the mask portion and the cover portion.

Hereinafter, embodiments of the invention will be described with reference to the drawings showing a portable computer.

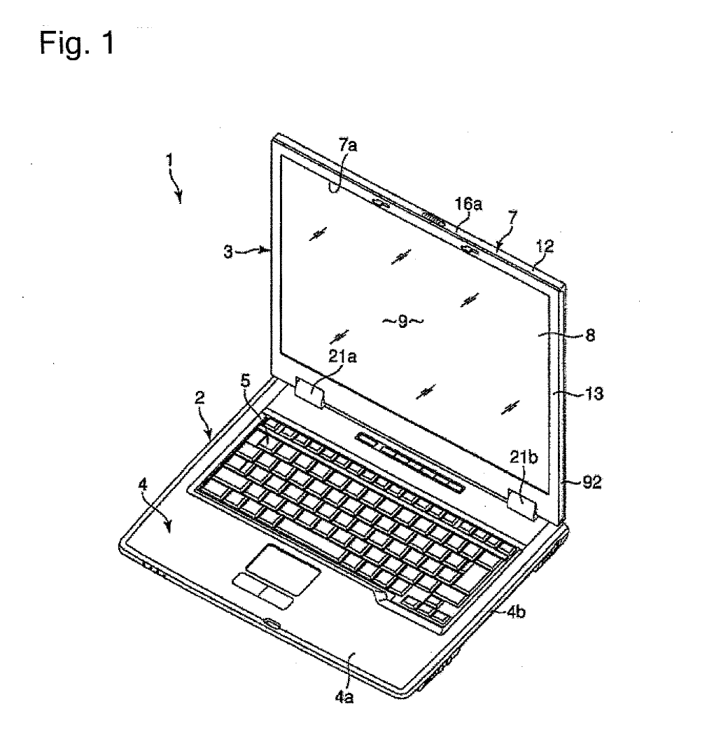

FIG. 1 shows a portable computer 1 which is an electronic apparatus of a first embodiment of the invention. As shown in FIG. 1, the portable computer 1 includes a body 2 and a display unit 3.

The body 2 has a body housing 4 which is formed into a box-like shape having: an upper wall 4a; a peripheral wall 4b; and a lower wall which is not shown. In the body 2, a circuit board and a plurality of electronic components are mounted inside the body housing 4. A keyboard 5 is supported by the upper wall 4a of the body housing 4.

As shown in FIG. 1, the display unit 3 has a display housing 7, and a display device 8 which is housed in the display housing 7. The display housing 7 is an example of the housing set forth in the claims. The display housing 7 has a window portion 7a.

Examples of the display device 8 are a liquid crystal display, a plasma display, an organic electroluminescence display, and a surface-conduction electron-emitter display. The display device 8 has a display screen 9. The display screen 9 is exposed to the outside of the display housing 7 through the window portion 7a.

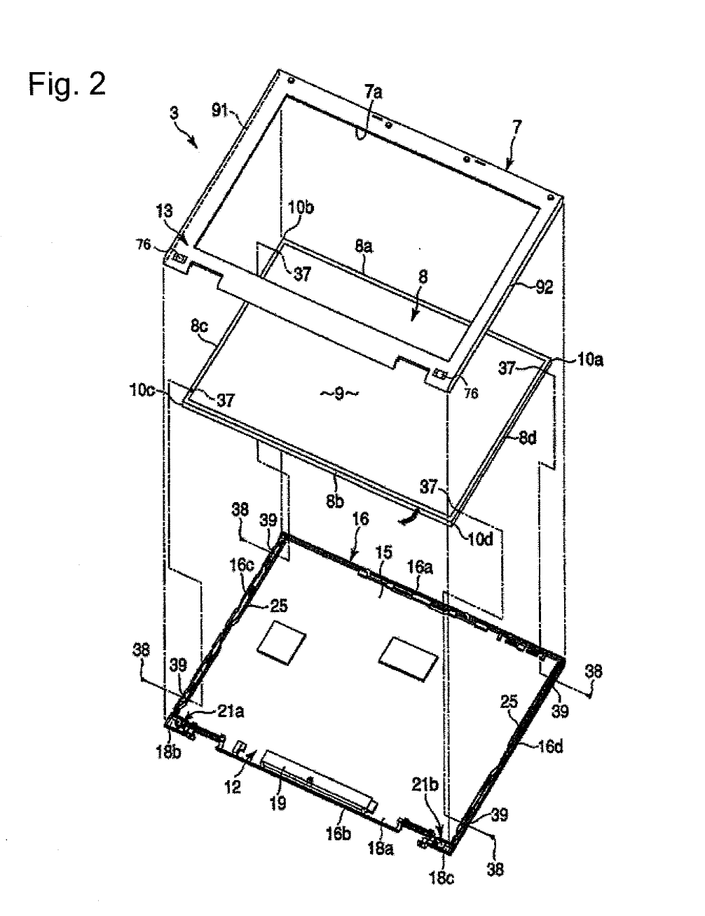

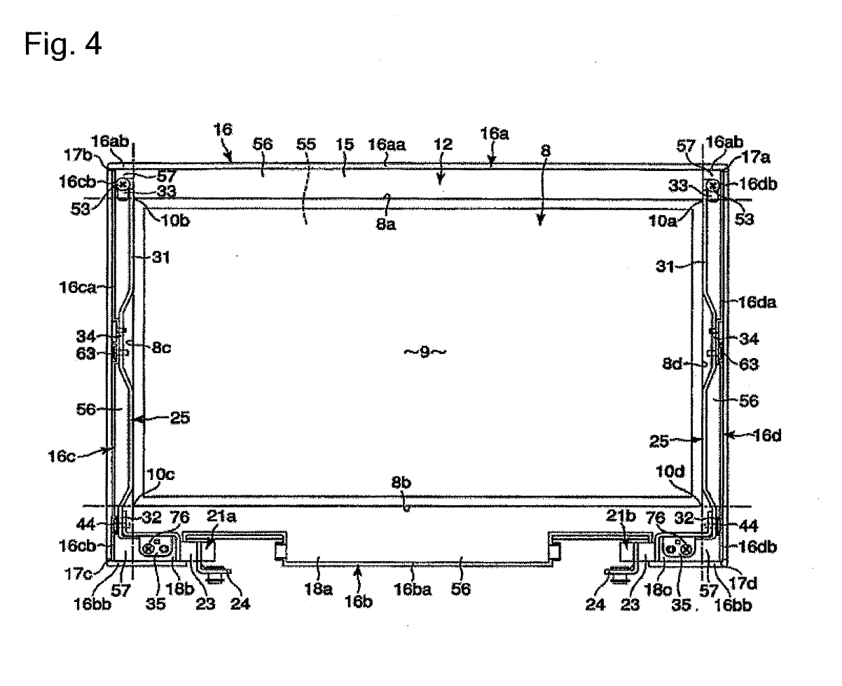

As shown in FIGS. 2 and 4, the display device 8 is formed into a rectangular plate-like shape, and has four of first to fourth side face portions 8a, 8b, 8c, 8d. The first side face portion 8a extends in the width direction of the portable computer 1, and, in a state where the display screen 9 is opposed to the user, is formed as the upper edge of the display device 8. The second side face portion 8b extends in parallel to the first side face portion 8a, and is formed as the lower edge of the display device 8. The third and fourth side face portions 8c, 8d extend in a direction perpendicular to the first side face portion 8a, and are formed as the left and right edges of the display device 8, respectively.

As shown in FIG. 4, the display device 8 has first to fourth corner portions 10a, 10b, 10c, 10d which are formed by the first to fourth side face portions 8a, 8b, 8c, 8d.

As shown in FIG. 2, the display housing 7 has a cover 12 and a mask 13. When the mask 13 is combined with the cover 12, they cooperate with each other to form the box-like display housing 7. In the embodiment, for example, the mask 13 is configured of a magnesium alloy material, and the cover 12 is configured of a plastic material.

FIG. 4 is a view schematically showing relationships between the cover 12 and the display device 8. The cover 12 has a back wall 15 and a peripheral wall 16. The back wall 15 is positioned on the back of the display device 8, and opposed to the back face (i.e., the face opposite to the display screen 9) of the display device 8. The back wall 15 is formed to be larger than the outer shape of the display device 8.

The peripheral wall 16 is raised from a peripheral edge portion of the back wall 15, and surrounds the side face portions 8a, 8b, 8c, 8d of the display device 8. Specifically, the peripheral wall 16 has an upper peripheral wall 16a, a lower peripheral wall 16b, a left peripheral wall 16c, and a right peripheral wall 16d. The upper peripheral wall 16a and the lower peripheral wall 16b extend in parallel to each other in the width direction of the portable computer 1. The left peripheral wall 16c and the right peripheral wall 16d extend in a direction perpendicular to the upper peripheral wall 16a. The left and right peripheral walls 16c, 16d are formed at positions which are slightly inside of the outer peripheral edge of the back wall 15 toward the inner side of the cover 12. As shown in FIG. 4, the cover 12 has first to fourth corner portions 17a, 17b, 17c, 17d which are formed by the peripheral walls 16a, 16b, 16c, 16d.

The upper peripheral wall 16a of the cover 12 has a first wall portion 16aa which is formed in a middle portion of the upper peripheral wall 16a, and which is opposed to the first side face portion 8a of the display device 8, and second wall portions 16ab which are formed in left and right end portions of the upper peripheral wall 16a, respectively, and which are not opposed to the display device 8. The lower peripheral wall 16b of the cover 12 has a first wall portion 16ba which is formed in a middle portion of the lower peripheral wall 16b, and which is opposed to the second side face portion 8b of the display device 8, and second wall portions 16bb which are formed in left and right end portions of the lower peripheral wall 16b, respectively, and which are not opposed to the display device 8.

The left peripheral wall 16c of the cover 12 has a first wall portion 16ca which is formed in a middle portion of the left peripheral wall 16c, and which is opposed to the third side face portion 8c of the display device 8, and second wall portions 16cb which are formed in upper and lower end portions of the left peripheral wall 16c, respectively, and which are not opposed to the display device 8. The right peripheral wall 16d of the cover 12 has a first wall portion 16da which is formed in a middle portion of the right peripheral wall 16d, and which is opposed to the fourth side face portion 8d of the display device 8, and second wall portions 16db which are formed in upper and lower end portions of the right peripheral wall 16d, respectively, and which are not opposed to the display device 8.

First to third projections 18a, 18b, 18c are disposed in a lower end portion of the cover 12. The first projection 18a is projected from a middle portion of the lower end portion of the cover 12 toward the outside of the cover 12. An electronic component 19 such as an inverter is accommodated in the first projection 18a. The second and third projections 18b, 18c are projected from left and right end portions of the cover toward the outside of the cover 12, respectively.

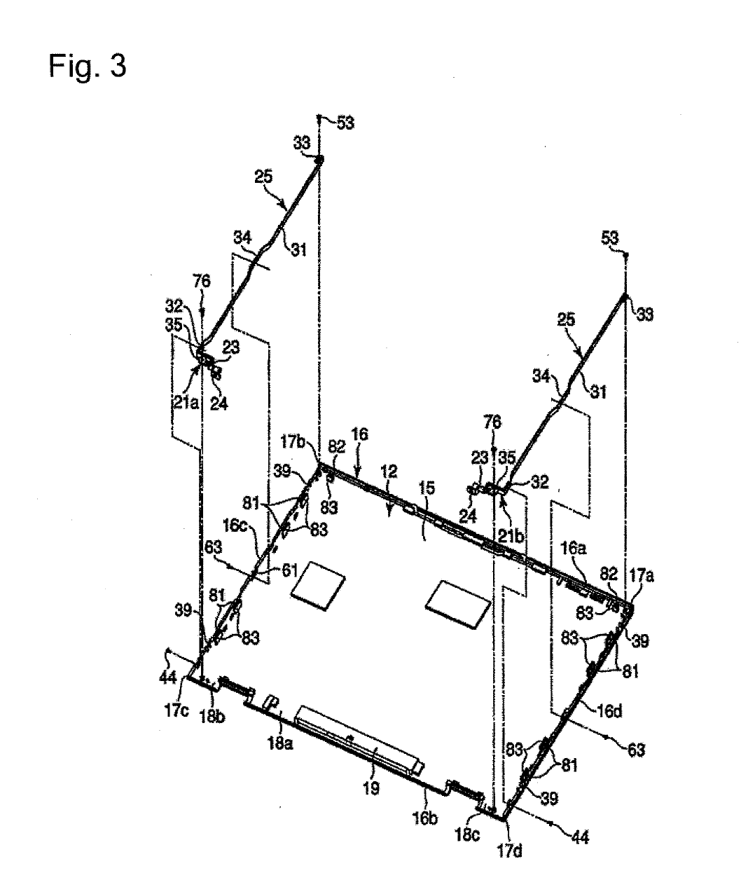

As shown in FIG. 1, the portable computer 1 has a pair of hinge mechanisms 21a, 21b through which the display housing 7 is swingably connected to the body housing 4. As shown in FIG. 3, each of the hinge mechanisms 21a, 21b has a hinge shaft 23, a first bracket 24, and a second bracket 25. The hinge shafts 23 are disposed between the display housing 7 and the body housing 4. In the first brackets 24, one end portion is connected to the hinge shaft 23, and the other end portion is fixed to the body housing 4. In the second brackets 25, one end portion is connected to the hinge shaft 23, and the other end portion is extended into the display housing 7 to be fixed to the display housing 7.

The first and second brackets 24, 25 are relatively swingable about the hinge shafts 23. The hinge shafts 23 swingably support the display housing 7 with respect to the body housing 4, through the first and second brackets 24, 25.

The brackets 25 are fixed to the display device 8 by screws 38. Specifically, the screws 38 are passed through screw through holes of the brackets 25, and engaged with screw holes 37 of the display device 8, whereby the brackets 25 are fixed to the display device 8. The screws 38 are attached to the screw through holes and the screw holes 37 along a direction perpendicular to the fourth side face portion 8d of the display device 8. Namely, the screws 38 are attached laterally with respect to the display device 8.

As shown in FIG. 4, the region in the cover 12 are partitioned to first to third regions 55, 56, 57. The first region 55 is positioned on the back of the display device 8, and opposed to the back face of the display device 8. The second regions 56 are formed respectively between the first wall portion 16aa of the upper peripheral wall 16a and the first side face portion 8a of the display device 8, between the first wall portion 16ba of the lower peripheral wall 16b and the second side face portion 8b of the display device 8, between the first wall portion 16ca of the left peripheral wall 16c and the third side face portion 8c of the display device 8, and between the first wall portion 16da of the right peripheral wall 16d and the fourth side face portion 8d of the display device 8.

The third regions 57 are formed in peripheral edge portions of the display housing 7 which are deviated from the first region 55 and the second regions 56. Namely, each of the third regions 57 is defined by any two adjacent ones of the second wall portions 16ab, 16bb, 16cb, 16db which are in the peripheral walls 16a, 16b, 16c, 16d. In other words, the third regions are formed between the corner portions 10a, 10b, 10c, 10d of the display device 8 and the corner portions 17a, 17b, 17c, 17d of the cover 12. The third regions 57 include not only a part of the back wall 15 of the cover 12, but also parts of the inner peripheral faces of the peripheral walls 16a, 16b, 16c, 16d.

As shown in FIG. 3, first and second ribs 81, 82 which are, for example, plural are raised from the second regions 56 of the back wall 15 of the cover 12. The first ribs 81 are formed between the third and fourth side face portions 8c, 8d of the display device 8 and the left and right peripheral walls 16c, 16d of the cover 12. The second ribs 82 are formed between the first side face portion 8a of the display device 8 and the upper peripheral wall 16a of the cover 12. The first and second ribs 81, 82 are opposed to the side face portions 8a, 8c, 8d of the display device 8.

As shown in FIG. 2, the mask 13 is combined with the cover 12. The mask 13 is opposed to the display screen 9 of the display device 8. The window portion 7a is formed in the mask 13. The mask 13 has left and right peripheral walls 91, 92. When the mask 13 is combined with the cover 12, the left and right peripheral walls 91, 92 are opposed from the outside to the left and right peripheral walls 16c, 16d of the cover 12, respectively. The left and right peripheral walls 16c, 16d of the cover 12 are covered by the peripheral walls 91, 92 of the mask 13. Notches 39 formed in the cover 12 are covered by the peripheral walls 91, 92 of the mask 13.

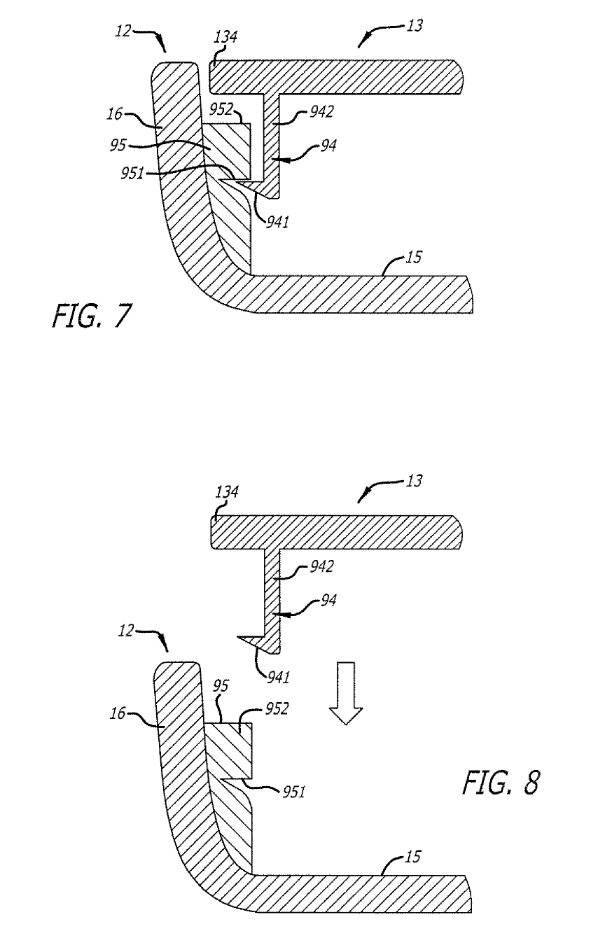

Engaging claws 94 which are, for example, plural are formed on the inner peripheral faces of the left and right peripheral walls 91, 92 of the mask 13. On the other hand, engaged portions 95 which correspond to the engaging claws 94 are disposed in the left and right peripheral walls 16c, 16d of the cover 12, and engaged with the engaging claws. Therefore, the mask 13 is detachably fixed to the cover 12. The engaging claws 94 and the engaged portions 95 will be described later with reference to FIGS. 7 and 8.

Next, the function of the portable computer 1 will be described.

The electronic component 19 is housed in the first projection 18a of the cover 12 in the embodiment. When the electronic component 19 generates heat, the mask 13 and the cover 12 are different from each other in coefficient of thermal expansion because they are configured of the different materials as described above.

When the portable computer 1 is activated and the electronic component 19 generates heat, the heat of the electronic component 19 is transmitted to the mask 13 and cover 12 which sandwich the both faces of the electronic component 19. In the embodiment, the coefficient of thermal expansion of the mask 13 which is configured of a plastic member is larger than that of the cover 12 which is configured of a magnesium alloy material. When the mask 13 and cover 12 which have different coefficients of thermal expansion are connected to each other, expansion and contraction of the cover 12 cannot follow those due to expansion of the mask 13, and stress is applied to connecting portions such as the regions where fixation is performed by the screws and the engaging claws. As a result, there is a possibility that the housing may be broken in the regions.

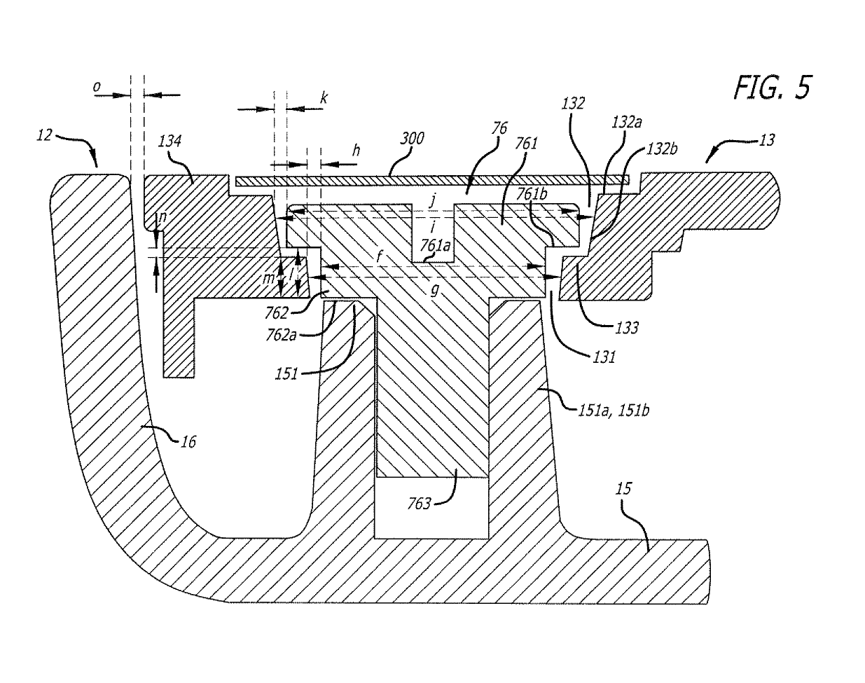

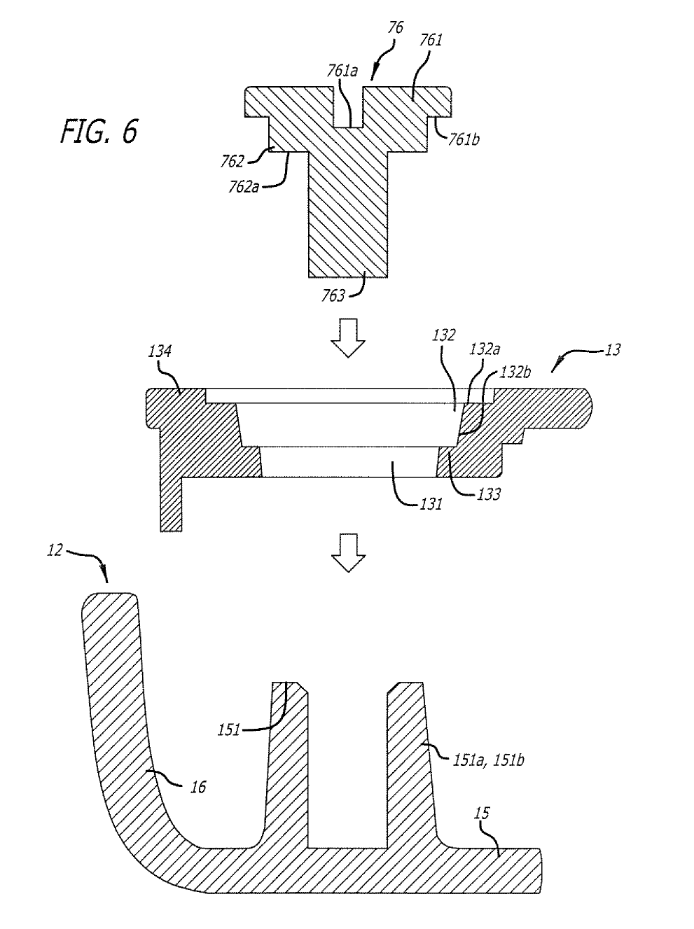

In the portable computer 1 of the embodiment, therefore, a gap is disposed in the connecting portions between the mask 13 and the cover 12 to allow the mask 13 to expand and contract by thermal expansion. This configuration will be specifically described with reference to FIGS. 5 and 6.

As shown in FIG. 5, the cover 12 has: the peripheral wall 16 which covers the side face portions 8a, 8b, 8c, 8d of the display device 8; the back wall 15; and screwed portions 151a, 151b which are to be screwed with screws 76. Between the side face portions 8a, 8b, 8c, 8d of the display device 8 and the peripheral wall 16 of the cover 12, the screwed portions 151a, 151b are raised from the back wall 15 of the cover 12 at positions separated from the peripheral wall 16, in the direction intersecting with the display screen of the display device 8.

Each of the screws 76 in the embodiment includes: an upper end portion 761 which has a recess 761a that receives external stress, and a first face 761b that, when the screw is screwed with the screwed portion 151a or 151b of the cover 12, butts against the upper face 151 of the screwed portion 151a or 151b; a middle portion 762 having a second face 762a for holding the mask 13 in the vicinity of the cover 12; and a screwing portion 763 that is screwed with the screwed portion 151a or 151b of the cover 12. As shown in FIG. 6, the screws are inserted into through-holes 131 of the mask 13, and screwed with the screwed portions 151a, 151b of the cover 12, thereby connecting the cover 12 and the mask 13 to each other.

The mask 13 in the embodiment has the through-holes 131 into which the screws 76 are to be inserted, and recesses 132 which are in the peripheries of the through-holes 131, and into which upper end portions 761 of the screws 76 are to be embedded. Each of the recesses 132 which are formed in the mask 13 in the embodiment has a first recess 132a into which a lid 300 for preventing the upper end portion 761 of the screw 76 from being exposed is to be inserted, and a second recess 132b having a held face 133 that is opposed to the second face 762a of the screw 76.

As shown in FIG. 5, in the embodiment, the width f of the middle portions 762 of the screws is designed to be narrower than the width g of the through-holes 131 of the mask 13, and hence a gap h is formed. The width i of the upper end portions 761 of the screws is designed to be narrower than the width j of the recesses 132 of the mask 13, and hence a gap k is formed. According to the configuration, when receiving heat from the electronic component 19, the mask 13 in the embodiment is allowed to expand or contract in the lateral direction of the drawing (a direction which is substantially perpendicular to the direction in which the screw 76 is inserted).

The height 1 of the middle portions 762 of the screws is formed to be larger than the depth m of the through-holes 131 of the mask 13, and hence a gap n is formed. Therefore, the mask 13 is allowed to be moved in the direction away from the cover 12. According to the configuration, when receiving heat from the electronic component 19, the mask 13 in the embodiment can expand or contract in the lateral direction of the drawing without resistance in the direction in which the screws 76 are inserted.

A gap o is formed between an end portion 134 of the mask 13 and the peripheral wall 16 of the cover 12. According to the configuration, when receiving heat from the electronic component 19, the mask 13 in the embodiment can expand or contract in the lateral direction of the drawing without suppression by the peripheral wall 16 of the cover 12.

Next, the engagement structure using the engaging claws 94 in the embodiment will be specifically described with reference to FIGS. 7 and 8.

As shown in FIG. 7, the engaging claws 94 are disposed on the inner peripheral faces of the left and right peripheral walls 91, 92 of the mask 13. On the other hand, the engaged portions 95 which correspond to the engaging claws 94 are disposed in the left and right peripheral walls 16c, 16d of the cover 12, and formed so as to be engaged with the engaging claws.

Each of the engaging claws 94 in the embodiment is configured by a claw portion 941 which is to be engaged with the corresponding engaged portion 95 of the cover 12, and a rib 942 which is raised from the upper wall 121 of the mask 13 in the direction intersecting with the display screen of the display device 8. Each of the engaged portions 95 in the embodiment is configured by an engaging face 951 which is to be engaged with the corresponding claw portion 941 of the mask 13, and an extended portion 952 which is extended from the peripheral wall 16. As shown in FIG. 8, the engaging claws 94 are engaged with the engaged portions 95 of the cover 12, whereby the cover 12 and the mask 13 are connected to each other.

As shown in FIG. 7, in the engaging claws 94 in the embodiment, the claw portions 941 are engaged with the engaging faces 951 while forming gaps p between the ribs 942 and the engaged portions 95 of the cover 12. When receiving heat from the electronic component 19, therefore, the mask 13 in the embodiment can expand or contract in the lateral direction of the drawing.

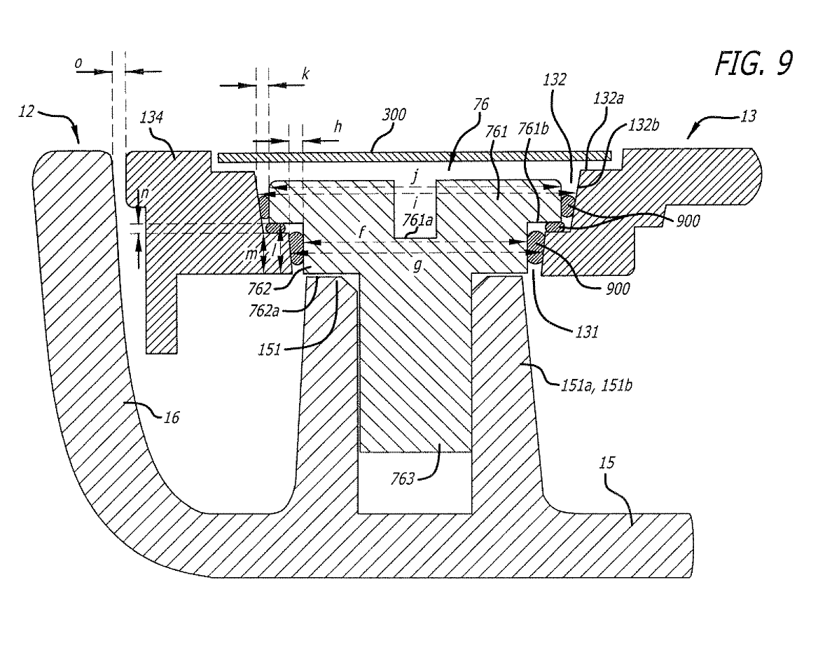

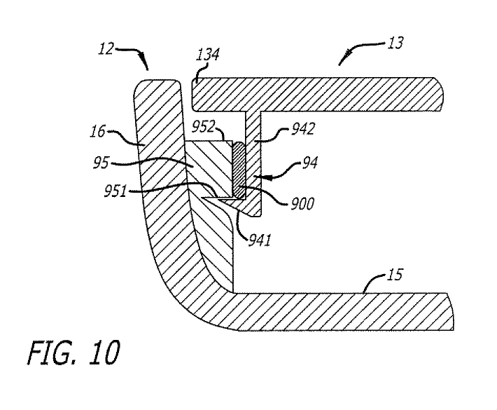

Next, the portable computer 1 which is an electronic apparatus of a second embodiment of the invention will be described with reference to FIGS. 9 and 10. The components which have similar or identical functions as those of the first embodiment are denoted by the same reference numerals, and their description is omitted.

In the portable computer 1, as shown in FIGS. 9 and 10, buffer members 900 are disposed in gaps formed in the connecting portions between the cover 12 and the mask 13. The buffer members 900 are configured of a flexible material. Specific examples of the material used in the buffer members 900 are materials having a restoring force for supporting the mask 13 in the steady state, and sponge, urethane foam, or the like is preferably used. The buffer members 900 are requested to have a section area which is necessary for avoiding interference between the mask 13 and the screws 76 and the like, and holding the mask 13. Therefore, the buffer members are disposed separately in plural number and in an intermittent manner. The configuration of the portable computer 1 other than described above is the same as that of the first embodiment.

In the portable computer 1 of the second embodiment configured as described above, the gaps formed in the connecting portions can be maintained to have a constant size, and interference between the mask 13 and the screws 76 and the like can be avoided.

The invention is not restricted to the above-described embodiments as they are, and, in the stage of implementation, the invention can be embodied while the components are modified without departing the spirit and scope of the invention. By appropriate combinations of plural components disclosed in the embodiments, various inventions can be configured. For example, some of the components can be omitted from all of the components shown in the embodiments. Moreover, the components in different embodiments can be appropriately combined.

What is claimed is:

1. An electronic apparatus comprising:
a housing;
a heating member in the housing; and
a display device in the housing, the display device having a display screen,
wherein the housing comprises:
a mask portion including an opening, the opening configured to expose the display screen therethrough;
a cover portion provided opposing to the mask portion with respect to the display device; and
at least two connecting portions configured to connect the mask portion and the cover portion, and to sandwich the heating member,
wherein each of the at least two connecting portions includes a gap portion that allows expansion and contraction of the housing due to thermal expansion between the connecting portion and at least one of the mask portion and the cover portion.

2. The electronic apparatus of claim 1, wherein the connecting portion includes a first gap portion having a gap in a first direction of expansion and contraction of the mask portion, and a second gap portion having a gap in a second direction intersecting with the first direction.

3. The electronic apparatus of claim 2, wherein:
the mask portion has a through-hole;
the cover portion has a hole;
the connecting portion has a connecting member configured to connect the mask portion and the cover portion by being inserted into the through-hole and the hole; and
the through-hole and the hole are different in shapes so that the gap portion is formed between the connecting member and at least one of the mask portion and the cover portion.

4. The electronic apparatus of claim 3, wherein the second gap portion allows the mask portion to move in a direction away from the cover portion.

5. The electronic apparatus of claim 4, wherein:
the connecting member is inserted into the through-hole formed in an end portion of the mask portion.

6. The electronic apparatus of claim 1, wherein the mask portion has a coefficient of thermal expansion that is different from a coefficient of thermal expansion of the cover portion.

7. The electronic apparatus of claim 2, wherein the connecting portion has flexible joining members disposed in the first and second gap portions in order to avoid interference between the connecting member and at least one of the mask portion and the cover portion.

8. The electronic apparatus of claim 3, wherein
the connecting member includes a screw, the screw configured to be inserted into the through-hole to be screwed with the hole, whereby the mask portion and the cover portion are connected to each other, and
a diameter of the through-hole is longer than a diameter of the screw.

9. The electronic apparatus of claim 8, wherein the screw has, in a state where the screw is screwed with the hole, a length exposed from the hole is longer than a width of the through-hole in a depth direction.
